(19) United States
(12) Patent Application Publication
(10) Pub. No.: US 2026/0317246 A1
(43) Pub. Date: Oct. 15, 2026

(54) FILM-ATTACHED MEMBER

(71) Applicant: KYOCERA Corporation, Kyoto-shi (JP)

(72) Inventors: Katsuya NAKAMOTO, Koka-shi (JP); Kazuhiro ISHIKAWA, Gamo-gun (JP)

(21) Appl. No.: 19/718,334

(22) Filed: Jun. 24, 2026

Related U.S. Application Data
(63) Continuation of application No. 18/565,056, filed on May 26, 2022, now abandoned.

(30) Foreign Application Priority Data
May 28, 2021 (JP) 2021-089977

(51) Int. Cl. C04B 41/50; C04B 41/00; C23C 14/18; C23C 14/58

(52) U.S. Cl. CPC C04B 41/5045; C04B 41/009; C23C 14/185; C23C 14/5853

(57) ABSTRACT

A film-attached member according to the present disclosure includes a base member made of a ceramic, and a film of an oxide, a fluoride, an acid fluoride, or a nitride of a rare earth element on at least a portion of one surface of the base member. An exposed portion of the surface of the base member has hydrophilicity, and a surface of the film has water repellency. Another film-attached member according to the present disclosure includes a base member made of quartz, and a film of an oxide, a fluoride, an acid fluoride, or a nitride of a rare earth element on at least a portion of one surface of the base member. An exposed portion of the surface of the base member has hydrophilicity, and a surface of the film has water repellency.

### CROSS-REFERENCE TO RELATED APPLICATIONS

This application is a continuation application of U.S. patent application Ser. No. 18/565,056, filed Nov. 28, 2023, which is a National Phase Entry of International Application No. PCT/JP2022/021566, filed May 26, 2022, which claims priority to Japanese Application No. 2021-089977 filed May 28, 2021. The disclosure of the above-referenced application is incorporated herein by reference.

### TECHNICAL FIELD

The present disclosure relates to a film-attached member.

### BACKGROUND OF THE INVENTION

When water repellency is imparted to a surface of a window glass or the like, a method of forming a film by applying or chemical-vapor depositing a low-molecular-weight fluorine compound, fluororesin, silicone, or the like has been typically used. However, in such a method, although large water droplets flow downward, a problem arises in that small water droplets stay in place without flowing downward, deteriorating visibility. Accordingly, there is a demand for a member that maintains water repellency and has a property (water-sheeting property) by which water droplets adhering thereto quickly flow downward.

To enhance the water-sheeting property, for example, Patent Document 1 proposes a water-repellent base including a base and a water-repellent film formed on at least one surface thereof. The water-repellent film includes a first water-repellent region and a second water-repellent region in contact with the first water-repellent region. The first water-repellent region has a water contact angle from 40° to 110°, and the second water-repellent region has a water contact angle higher than the water contact angle of the first water-repellent region by 20° or more.

The first water-repellent region is made of a layer containing at least one selected from the group consisting of a compound containing a polyfluoroalkyl group or a polyfluoroether alkyl group, an oxide containing hafnium, an oxide containing zirconium, and an oxide containing aluminum, and the second water-repellent region is made of a layer containing a compound containing a polyfluoroalkyl group or a polyfluoroether alkyl group.

### CITATION LIST

### Patent Literature

Patent Document 1: JP 2013-133264 A

### SUMMARY

A film-attached member according to the present disclosure includes a base member made of a ceramic, and a film of an oxide, a fluoride, an acid fluoride, or a nitride of a rare earth element on at least a portion of one surface of the base member. An exposed portion of the surface of the base member has hydrophilicity, and a surface of the film has water repellency.

A film-attached member according to the present disclosure includes a base member made of quartz, and a film of an oxide, a fluoride, an acid fluoride, or a nitride of a rare earth element on at least a portion of one surface of the base member. An exposed portion of the surface of the base member has hydrophilicity, and a surface of the film has water repellency.

### BRIEF DESCRIPTION OF THE DRAWINGS

FIG. 1 is a plan view illustrating a film-attached member of a non-limiting embodiment of the present disclosure.

FIG. 2 is a plan view illustrating a film-attached member of a non-limiting embodiment of the present disclosure.

FIG. 3 is a plan view illustrating a plasma treatment device member of a non-limiting embodiment of the present disclosure.

FIG. 4 is a plan view illustrating the film-attached member of the non-limiting embodiment of the present disclosure.

FIG. 5 is a plan view illustrating a film-attached member of a non-limiting embodiment of the present disclosure.

FIG. 6 is a schematic view illustrating a sputtering device for obtaining a film-attached member of a non-limiting embodiment of the present disclosure.

### DESCRIPTION OF EMBODIMENTS

When a first water-repellent region and/or a second water-repellent region is formed of a layer containing an organic component such as a polyfluoroalkyl group as in Patent Document 1, there is a problem in that deterioration occurs in a short period of time when used in an environment irradiated with ultraviolet light or plasma.

The present disclosure provides a film-attached member capable of maintaining a water-sheeting property over a long period of time even when used in an environment irradiated with ultraviolet light or plasma.

The film-attached member according to the present disclosure is capable of maintaining a water-sheeting property over a long period of time even when used in an environment irradiated with ultraviolet light or plasma.

### Film-Attached Member

In the following, detailed description will be made of a film-attached member according to a non-limiting embodiment of the present disclosure with reference to the drawings. However, the figures referenced below illustrate in a simplified manner only main members necessary for description of the embodiments. Thus, the film-attached member may include any constituent member not illustrated in each of the figures referenced. The dimensions of the members in the drawings do not faithfully represent the actual dimensions of the constituent members, the dimension ratios of the members, or the like.

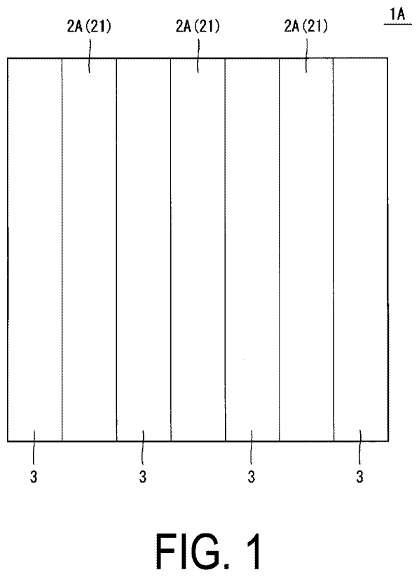

As in the example illustrated in FIG. 1, a film-attached member 1A includes a base member 2A made of a ceramic, and a film 3 of an oxide, a fluoride, an acid fluoride, or a nitride of a rare earth element on at least a portion of one surface of the base member 2A. An exposed portion 21 of the surface of the base member 2A has hydrophilicity, and a surface of the film 3 has water repellency. In these cases, the base member 2A and the film 3 are formed of an inorganic compound, and thus are capable of maintaining a water-sheeting property over a long period of time even when used in an environment where they are irradiated with ultraviolet light or plasma.

The ceramic as the material of the base member 2A may contain aluminum oxide as a main component. A main component means a component that accounts for most of the total of 100 mass % of all components constituting the ceramic. The main component may be equal to or greater than 80 mass %, for example. When the main component of the ceramic is aluminum oxide, the main component may contain at least one of silicon, magnesium, and calcium as an oxide.

Each component constituting the ceramic can be identified by an X-ray diffractometer using CuKα radiation. The content of each identified component can be determined by using, for example, an inductively coupled plasma (ICP) emission spectrophotometer or a fluorescent X-ray analysis device.

Examples of the oxide, fluoride, acid fluoride, or nitride of a rare earth element as the material of the film 3 include yttria (yttrium oxide: Y₂O₃₋ₓ (0≤x≤1)), yttrium fluoride (YF₃), yttrium oxyfluoride (YOF, Y₅O₄F₇, Y₅O₆F₇, Y₆O₅F₈, Y₇O₆F₉, Y₁₇O₁₄F₂₃), and yttrium nitride (YN).

The components constituting the film 3 need only be identified by using a thin film X-ray diffractometer.

The film 3 does not necessarily only contain a compound of a rare earth element, and may contain fluorine (F), sodium (Na), magnesium (Mg), aluminum (Al), silicon (Si), phosphorus (P), sulfur(S), chlorine (Cl), potassium (K), calcium (Ca), titanium (Ti), chromium (Cr), manganese (Mn), iron (Fe), cobalt (Co), nickel (Ni), copper (Cu), zinc (Zn), strontium (Sr), or the like in addition to the rare earth element, depending on the purity of the target used for forming the film 3, the device configuration, and the like.

The hydrophilicity and the water repellency may be evaluated by a static contact angle with respect to pure water (hereinafter, also simply referred to as “contact angle”). The phrase “having hydrophilicity” may mean that the static contact angle with respect to pure water is less than 90°, and the phrase “having water repellency” may mean that the static contact angle with respect to pure water is greater than 90°. The static contact angle may be determined under the following measurement conditions by using a surface contact angle measuring device “CA-X type” or a successor model thereof (available from Kyowa Interface Science Co., Ltd.), for example.
Solvent: Pure water
Droplet amount: 1 mm³
Holding time: 5 seconds
Measured 48 hours after film formation

When the ceramic contains aluminum oxide as a main component, the contact angle of the exposed portion 21 of the surface of the base member 2A with respect to pure water may be from 60° to 80°. When the material of the film 3 is yttria, the contact angle of the surface of the film 3 with respect to pure water may be from 92° to 110°.

The surface of the film 3 may have an average value of a root mean square slope (RΔq) in a roughness curve being equal to or less than 0.3. In this case, the contact angle of the surface of the film 3 with respect to pure water is as large as equal to or greater than 93°, and thus water droplets adhering to the film 3 can be readily repelled. Note that the surface of the film 3 may have an average value of a root mean square slope (RΔq) in a roughness curve being equal to or greater than 0.001.

The surface of the film 3 may have an average value of a cut level difference (Rδc) representing a difference between a cut level at a load length ratio of 25% in a roughness curve and a cut level at a load length ratio of 75% in the roughness curve (hereinafter, also simply referred to as “average value of the cut level difference (Rδc)” being equal to or less than 0.17 μm. In this case, the contact angle of the surface of the film 3 with respect to pure water becomes equal to or greater than 98°, and thus water droplets adhering to the film 3 can be even more readily repelled. Note that the surface of the film 3 may have an average value of the cut level difference (Rδc) being equal to or greater than 0.01 μm.

The root mean square slope (RΔq) and the cut level difference (Rδc) may be obtained, for example, in accordance with JIS B 0601:2001 by drawing the following four lines to be measured at substantially equal intervals within the measurement range, measuring the line roughness, and calculating the respective average values. In this case, the number of lines to be measured for each surface is 12 in total. The measurement conditions may be set, for example, as follows.
Measurement device: Shape analysis laser microscope (VK-X1100 or a successor model thereof available from KEYENCE CORPORATION)
Illumination: Coaxial epi-illumination
Cut-off value λs: None
Cut-off value λc: 0.08 mm
Cut-off value λf: None
Correction for terminal end effect: Yes
Measurement multiplication factor: 480× (20×24)
Measurement locations: 3
Measurement range: 710 μm×533 μm/location
Length of each line measured: 560 μm

The exposed portion 21 of the surface of the base member 2A may have an average value of a root mean square slope (RΔq) in a roughness curve being equal to or greater than 0.001. In this case, the contact angle of the exposed portion 21 of the surface of the base member 2A with respect to pure water becomes equal to or less than 78°, and thus water droplets can readily flow away. Note that the exposed portion 21 of the surface of the base member 2A may have an average value of a root mean square slope (RΔq) in a roughness curve being equal to or less than 0.284, and particularly equal to or less than 0.2.

The exposed portion 21 of the surface of the base member 2A may have an average value of the cut level difference (Rδc) being equal to or greater than 0.01 μm. In this case, the contact angle of the exposed portion 21 of the surface of the base member 2A with respect to pure water becomes equal to or less than 66°, and thus water droplets can even more readily flow away. Note that the exposed portion 21 of the surface of the base member 2A may have an average value of the cut level difference (Rδc) being equal to or less than 0.14 μm.

The base member 2A may be translucent. For example, when the base member 2A is made of a translucent ceramic, the base member 2A is translucent. A base member 2B made of quartz described below is also translucent. Note that translucent ceramic refers to a ceramic having a total light transmittance equal to or greater than 93%, such as, for example, translucent alumina, translucent yttria, and translucent YAG. The total light transmittance may be determined in accordance with JIS K7361-1:1997.

The average value of an arithmetic mean roughness (Ra) of the exposed portion 21 of the surface of the base member 2A may be from 0.004 μm to 0.17 μm. The arithmetic mean roughness (Ra) may be, for example, a value measured under the measurement conditions described above in accordance with JIS B 0601:2001.

The surface of the film 3 may be a polished surface. In this case, the contact angle of the surface of the film 3 with respect to pure water can be made larger than that of a film formation surface (AS-DEPO surface).

The surface of the film 3 may have an area larger than that of the exposed portion 21 of the surface of the base member 2A provided with the film 3. In this case, the possibility that a water film will occur is reduced, improving a washing efficiency. When the base member 2A is made of a translucent ceramic, visibility is ensured. This is also true for the base member 2B made of quartz described below. That is, for the base member 2B made of quartz as well, visibility is ensured.

The film 3 may have a thickness equal to or greater than 5 μm. In this case, the film 3 can be used for a long period of time even in an environment exposed to plasma. Note that the thickness of the film 3 may be equal to or greater than 8 μm. The thickness of the film 3 may be equal to or less than 50 μm.

The surface of the film 3 may be flat, or the film 3 may have a convex shape with a degree of flatness equal to or greater than 3 μm. In this case, water droplets readily move from a center portion toward a peripheral edge portion of the film 3, thereby improving the water-sheeting property. Note that the flatness of the film 3 may be equal to or less than 70 μm. When the film 3 has a circular shape, for example, respective heights of a center, an inner circumference, and an outer circumference of the circle are measured by using a three-dimensional measuring device (CRYSTA-Apex S9106 or a successor model thereof available from Mitutoyo Corporation), for example, and a maximum value of a difference between the respective heights may be regarded as the flatness of the film 3. A tip end diameter of a stylus used in this measurement is, for example, 1 mm.

The number of measurements varies depending on a diameter of the film 3. For example, when the diameter of the film 3 is from 400 mm to 600 mm, the measurement may be taken at, for example, 29 locations radially from the center of the circle. When the diameter of the film 3 is from 400 mm to 600 mm and a through-hole is formed at the center, the measurement may be taken at, for example, 28 locations radially from the center of the circle.

The film 3 may be formed by a physical vapor deposition (PVD) method. In other words, the film 3 may be a PVD film.

As in the example illustrated in FIG. 1, there may be a plurality of the exposed portions 21. In plan view, the plurality of exposed portions 21 may each have a linear shape (strip shape). The film 3 may be located between the exposed portions 21 adjacent to each other. That is, the exposed portions 21 and the films 3 may have a stripe shape in plan view.

Detailed description of a film-attached member 1B according to a non-limiting embodiment of the present disclosure will now be made with reference to the drawings. In the following, differences of the film-attached member 1B from the film-attached member 1A will be mainly described, and detailed descriptions of elements having the same configuration as those of the film-attached member 1A may be omitted.

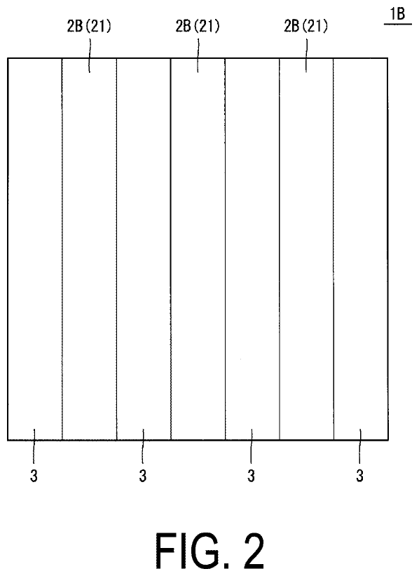

As in the example illustrated in FIG. 2, the film-attached member 1B includes the base member 2B made of quartz, and the film 3 of an oxide, a fluoride, an acid fluoride, or a nitride of a rare earth element on at least a portion of one surface of the base member 2B. The exposed portion 21 of the surface of the base member 2B has hydrophilicity, and the surface of the film 3 has water repellency. In these cases, the base member 2B and the film 3 are formed of an inorganic compound, and thus are capable of maintaining a water-sheeting property over a long period of time even when used in an environment irradiated with ultraviolet light or plasma.

The contact angle of the exposed portion 21 of the surface of the base member 2B with respect to pure water may be from 50° to 63°.

The surface of the film 3 of the film-attached member 1B may have an average value of a root mean square slope (RΔq) in a roughness curve being equal to or less than 0.009. In this case, the contact angle of the surface of the film 3 with respect to pure water becomes equal to or greater than 102°, and thus water droplets adhering to the film 3 can be readily repelled. Note that the surface of the film 3 of the film-attached member 1B may have an average value of a root mean square slope (RΔq) in a roughness curve being equal to or greater than 0.001.

The surface of the film 3 of the film-attached member 1B may have an average value of the cut level difference (Rδc) being equal to or less than 0.01 μm. In this case, the contact angle of the surface of the film 3 with respect to pure water becomes equal to or greater than 103°, and thus water droplets adhering to the film 3 can be even more readily repelled. Note that the surface of the film 3 of the film-attached member 1B may have an average value of the cut level difference (Rδc) being equal to or greater than 0.006 μm.

The exposed portion 21 of the surface of the base member 2B may have an average value of a root mean square slope (RΔq) in a roughness curve being equal to or greater than 0.002. In this case, the contact angle of the exposed portion 21 of the surface of the base member 2B with respect to pure water becomes equal to or less than 60°, and thus water droplets can readily flow away. Note that the exposed portion 21 of the surface of the base member 2B may have an average value of a root mean square slope (RΔq) in a roughness curve being equal to or less than 0.004.

The exposed portion 21 of the surface of the base member 2B may have an average value of the cut level difference (Rδc) being equal to or greater than 0.004 μm. In this case, the contact angle of the exposed portion 21 of the surface of the base member 2B with respect to pure water becomes equal to or less than 8°, and thus water droplets can even more readily flow away. Note that the exposed portion 21 of the surface of the base member 2B may have an average value of the cut level difference (Rδc) being equal to or less than 0.006 μm.

The film-attached member 1A and the film-attached member 1B may have the following configuration.

The film 3 may be made of yttrium oxide, a full width at half maximum (FWHM) of a diffraction peak on a (222) plane of the yttrium oxide obtained by X-ray diffraction may be equal to or less than 0.12°, and a coefficient of variation of the full width at half maximum may be equal to or less than 0.03. When the full width at half maximum and the coefficient of variation thereof are within these ranges, a crystallinity is high, residual stress is low, and variations thereof are suppressed, resulting in a low likelihood of a minute crack occurring in the film 3. Note that, although only upper limits are defined for the full width at half maximum and the coefficient of variation thereof, the full width at half maximum cannot be 0 and thus naturally does not include 0. In particular, the full width at half maximum is from 0.06° to 0.1°.

The device used for X-ray diffraction is, for example, EmPyrean (available from Spectris Co., Ltd.). When this device is used, the measurement conditions are as follows.
Measurement range 2θ: From 20° to 80°
X-ray power setting: 40 mA, 45 kV
Scan step time: 29 seconds
Step size: 0.013°
Divergence slit type: Fixed
Divergence slit size: 0.25°
Emitted light: CuKα1 (Kα2 removed)

When the coefficient of variation of the full width at half maximum is calculated, the number of measurements of the full width at half maximum is, for example, 9. When the film 3 has a circular shape, the emission locations of the X-rays are, for example, the center, locations at intervals of 90° on a virtual circumference on the inner circumferential side, and locations at intervals of 90° on the virtual circumference on the outer circumferential side.

A geometric mean of a compressive stress σ11 generated in the surface of the film 3 and a compressive stress σ2 generated in the surface in a direction perpendicular to the compressive stress σ11 may be equal to or greater than 120 MPa, and a coefficient of variation of the geometric mean may be equal to or less than 0.2.

When the geometric mean is equal to or greater than the 120 MPa, the hardness of the film 3 increases, making particles less likely to detach from the film 3 even when impacted by particles floating in the plasma treatment device, thereby reducing the risk of detached particles floating and contaminating the inside of the plasma treatment device.

When the coefficient of variation of the geometric mean is equal to or less than 0.2, the film 3 can withstand the tensile stress generated in the interior thereof even when the film 3 is used in an environment of repeated temperature rise and temperature fall, making it possible to reduce the likelihood of breakage of the film 3.

Values of the compressive stress σ11 and the compressive stress σ22 may be determined by a two-dimensional (2D) method by using an X-ray diffractometer.

When the coefficient of variation of the geometric mean is calculated, the number of measurements of the compressive stress σ11 and the compressive stress σ22 is, for example, 9. When the film 3 has a circular shape, the emission locations of the X-rays are, for example, the center, locations at intervals of 90° on a virtual circumference on the inner circumferential side, and locations at intervals of 90° on the virtual circumference on the outer circumferential side.

### Method of Manufacturing Film-Attached Member

A method of manufacturing the film-attached member according to a non-limiting embodiment of the present disclosure will now be described with reference to an example in which the film-attached member 1A is manufactured.

First, the base member 2A made of a ceramic may be prepared. Then, the film 3 may be formed on at least a portion of one surface of the prepared base member 2A by a PVD method to obtain the film-attached member 1A.

Specifically, description will be made of a method of manufacturing a base member made of a ceramic having a main component of aluminum oxide.

An aluminum oxide (Al₂O₃) A powder having an average particle diameter from 0.4 μm to 0.6 μm and an aluminum oxide B powder having an average particle diameter of about from 1.2 μm to 1.8 μm are prepared. A silicon oxide (SiO₂) powder is prepared as a Si source, and a calcium carbonate (CaCO₃) powder is prepared as a Ca source. Note that, as the silicon oxide powder, a fine powder having an average particle diameter equal to or less than 0.5 μm is prepared. To obtain an alumina ceramic containing Mg, magnesium hydroxide powder is used. Note that, in the following description, powders other than the aluminum oxide A powder and the aluminum oxide B powder are collectively referred to as first sub-component powders.

Then, a predetermined amount of each of the first sub-component powders is weighed. The aluminum oxide A powder and the aluminum oxide B powder are then weighed in a mass ratio from 40:60 to 60:40 so that the content of Al converted to Al₂O₃ is equal to or greater than 99.4 mass % out of 100 mass % of the components constituting the obtained ceramic, thereby obtaining a blended aluminum oxide powder. The first sub-component powders are weighed so that, after first determining the amount of Na in the blended aluminum oxide and converting the amount of Na when made into a ceramic to Na₂O, the ratio of this converted value to the value of the components constituting the first sub-component powders (in this example, Si, Ca, and the like) converted to oxide is equal to or less than 1.1.

Then, with respect to 100 total parts by mass of the blended aluminum oxide powder and the first sub-component powders, from 1 to 1.5 parts by mass of a binder such as polyvinyl alcohol (PVA), 100 parts by mass of a solvent, and from 0.1 to 0.55 parts by mass of a dispersing agent are provided to an agitation device and mixed and agitated to obtain a slurry.

Subsequently, the slurry is spray-granulated to obtain granules, and the granules are molded into a predetermined shape by a powder press molding device, an isostatic press molding device, or the like, and machined as necessary to obtain a powder compact having a substrate shape.

The powder compact is then fired at a firing temperature of from 1500° C. to 1700° C. and with a retention time of from 4 hours to 6 hours to obtain a sintered body. The surface of the sintered body on which the film is to be formed is ground to obtain a ground surface, and the ground surface is subsequently roughly polished by using diamond abrasive grains having an average particle diameter equal to or greater than 4 μm and a polishing disk made of cast iron. In the rough polishing, after the diamond abrasive grains having a large average particle diameter are used, diamond abrasive grains having a small average particle diameter may be used. Subsequently, the surface is finished by using diamond abrasive grains having an average particle diameter of from 1 μm to 5 μm and a polishing plate made of tin, whereby the base member 2A (2B) can be obtained. After the finishing, the surface may be polished by using colloidal silica, ceria, or alumina abrasive grains and a polishing pad obtained by impregnating a nonwoven fabric formed of polyester fibers with polyurethane. The average particle diameter of the colloidal abrasive grains described above is, for example, from 20 μm to 50 μm.

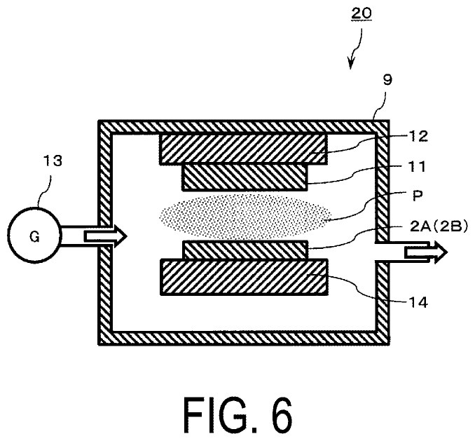

A method of forming the film will now be described with reference to FIG. 6.

FIG. 6 is a schematic view illustrating a sputtering device 20. The sputtering device 20 includes a chamber 9, a gas supply source 13 leading into the chamber 9, an anode electrode 14 and a cathode electrode 12 located inside the chamber 9, and a target 11 connected to the cathode electrode 12 side.

As a method of forming the film, the base member 2A (2B) obtained by the method described above is installed on the anode electrode 14 side inside the chamber 9. On the opposite side in the chamber 9, the target 11 containing a rare earth element, in this case, metal yttrium, as a main component is installed on the cathode electrode 12 side. In this state, the inside of the chamber 9 is depressurized by an exhaust pump, and argon and oxygen are supplied as a gas G from the gas supply source 13. Here, the argon gas is supplied at a pressure from 0.1 Pa to 2 Pa, and the oxygen gas is supplied at a pressure from 1 Pa to 5 Pa.

Then, an electric field is applied between the anode electrode 14 and the cathode electrode 12 by a power supply to generate and sputter a plasma P1, thereby forming a metal yttrium film on the surface of the base member 2A (2B). Note that the thickness per formation is sub-nm. A plasma P2 is then generated to oxidize the metal yttria film. Then, the film-attached member 1A (1B) including the yttrium oxide film can be obtained by alternately forming the metal yttrium oxide film and executing an oxidization process to layer the film so that the total thickness of the film is from 5 μm to 50 μm. Note that the reference sign P in FIG. 6 represents the plasma P1 or the plasma P2.

In the plasma P1, among optical spectra of the plasma P1, a first spectrum having the highest intensity is located at wavelengths from 390 nm to 430 nm, and other optical spectra (second spectrum, third spectrum, and fourth spectrum in descending order of intensity) are located at wavelengths from 300 nm to 700 nm.

In the plasma P2, among optical spectra of the plasma P2, a first spectrum having the highest intensity is located at wavelengths from 500 nm to 550 nm, and other optical spectra (second spectrum, third spectrum, and fourth spectrum in descending order of intensity) are located at wavelengths from 380 nm to 820 nm.

To form a film of yttrium fluoride, the oxidation process need only be replaced by a fluorination process.

To form a film of yttrium acid fluoride, formation of a metal yttrium film and an oxidation process as well as a fluorination process need only be alternately performed in this order for layering.

To form a film of yttrium nitride, the oxidation process need only be replaced with a nitriding process.

Note that the power supplied from the power supply may be either high-frequency power or direct current power.

Note that examples of the method of manufacturing the film-attached member 1B include the same manufacturing method as that of the film-attached member 2A except that the base member 2B made of quartz is prepared instead of the base member 1A made of a ceramic.

### Antifouling Member

Detailed description will now be made of an antifouling member according to a non-limiting embodiment of the present disclosure.

The antifouling member of the non-limiting embodiment of the present disclosure includes the film-attached member 1A. In this case, the water-sheeting property can be maintained over a long period of time even with use in an environment irradiated with ultraviolet light or plasma.

The antifouling member may be a member used in a flowing water environment. Examples of the antifouling member include members utilized in a flowing water environment such as a toilet, a toilet bowl, a washbowl of a washstand, a kitchen sink, a shower nozzle, tableware, a toilet pipe, a water pipe, a faucet, a bidet washing nozzle, a washing tub, a dishwasher, a roof, an outer wall of a building, and pavement; and tableware, a bathtub, a bathroom wall, a bathroom floor, a bathroom fixture, an automobile, a railway vehicle, an aircraft, and tiles that utilize flowing water for washing and the like. Note that the antifouling member may include the film-attached member 1B instead of the film-attached member 1A.

### Plasma Treatment Device Member

A plasma treatment device member according to a non-limiting embodiment of the present disclosure will now be described with reference to the drawings by exemplifying a case where the plasma treatment device member includes the film-attached member 1A described above.

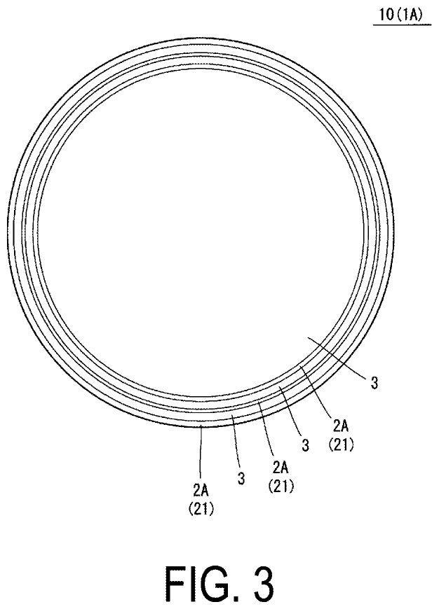

A plasma treatment device member 10 in the example illustrated in FIG. 3 is a top plate of a treatment vessel in a plasma treatment device and includes the film-attached member 1A. In this case, the water-sheeting property can be maintained over a long period of time even with use in an environment irradiated with ultraviolet light or plasma.

When the plasma treatment device member 10 includes the film-attached member 1A, the base member 2A may have a disk shape. The exposed portion 21 may have an annular shape extending along a peripheral edge portion of the base member 2A in plan view. The surface of the film 3 located at a center portion may have the largest area. Note that the plasma treatment device member 10 may include the film-attached member 1B instead of the film-attached member 1A.

The film-attached members 1A, 1B of the present disclosure described above can maintain a water-sheeting property over a long period of time. Therefore, plasma treatment device members to which reaction products caused by the plasma are likely to adhere and which need to be repeatedly removed and cleaned, such as a high-frequency transmission window member for transmitting high-frequency waves for generating plasma and a susceptor for mounting a semi-conductor wafer, for example, may include the film-attached members 1A, 1B. The plasma treatment device member may be a top plate, a side wall, or the like of a chamber including an internal space for plasma treatment.

### Plasma Treatment Device

Description will now be made of a plasma treatment device according to a non-limiting embodiment of the present disclosure.

The plasma treatment device according to the non-limiting embodiment of the present disclosure includes the plasma treatment device member 10 described above. In this case, the water-sheeting property can be maintained over a long period of time even with use in an environment irradiated with ultraviolet light or plasma.

The embodiments according to the present disclosure are described above. However, the present disclosure is not limited to the embodiments described above, and naturally includes variations within a scope that does not deviate from the spirit of the present disclosure.

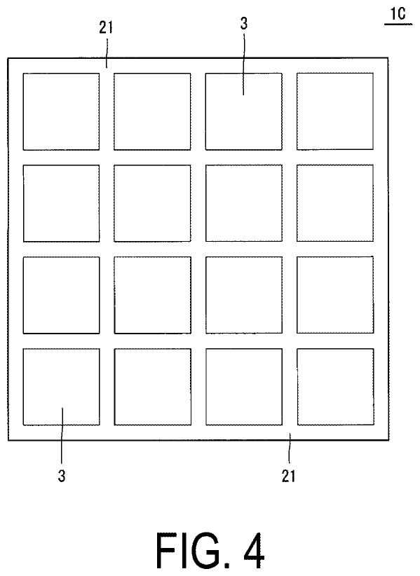

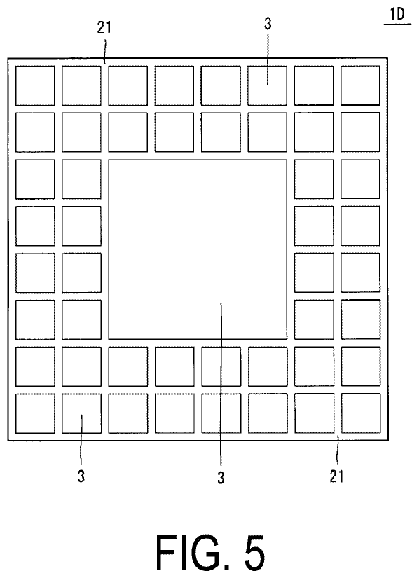

For example, the shape of the exposed portion 21 in plan view is not limited to the illustrated shape. FIGS. 4 and 5 are each a diagram illustrating a variation of the shape of the exposed portion 21. As in the example illustrated in FIG. 4, the exposed portion 21 in a film-attached member 1C may have a lattice shape in plan view. As in the example illustrated in FIG. 5, the exposed portion 21 in a film-attached member 1D may have a lattice shape and surround the center portion in plan view. The surface of the film 3 located at a center portion may have the largest area. The shape of the film is illustrated as rectangular in FIGS. 1 and 2, circular and annular in FIG. 3, and square in FIG. 5, but may be helical or a combination of these shapes.

The present disclosure will be described in detail below using examples, but the present disclosure is not limited to the following examples.

### EXAMPLES

### Sample Nos. 1 to 4

### Fabrication of Test Piece

First, the base members shown in Table 1 were prepared. Note that base members having a plate shape and made of a ceramic, containing 99.6 mass % of aluminum oxide, and made of quartz were prepared. Aluminum oxides (1), (2) shown in Table 1 were as follows.
Aluminum oxide (1): 0.1 μm average value of arithmetic mean roughness (Ra)
Aluminum oxide (2): 0.03 μm average value of arithmetic mean roughness (Ra)

Note that the arithmetic mean roughness (Ra) is a value measured in accordance with JIS B 0601:2001. A shape analyzing laser microscope (“VK-X1100” available from KEYENCE CORPORATION) was used as a measuring instrument, and other measurement conditions were as described above.

A film was formed on one surface of each base member to obtain a test piece. The film formation method, the material of the film, and the thickness of the film were as follows.
Film-formation method: Manufacturing method described above
Material of film: Yttria
Thickness of film: 10 μm

### Evaluation

For each obtained test piece, the static contact angle with respect to pure water was measured 48 hours after film formation. The measurement method is described below.

Static Contact Angle with Respect to Pure Water

Measuring device: Surface contact angle measuring device “CA-X type” available from Kyowa Interface Science Co., Ltd.
Solvent: Pure water
Droplet amount: 1 mm³
Holding time: 5 seconds

Other: Measurement was performed at n=5, and the average value and the standard deviation were calculated. The results are shown in the “Contact angle” column in Table 1.

TABLE 1

Contact angle (°)

| | | | |
|---|---|---|---|
| Sample | Test piece | Average | Standard |

| No. | Base member | Film | value | deviation |
|---|---|---|---|---|
| 1 | Aluminum oxide (1) | N/A | 66.2 | 0.6 |
| | Aluminum oxide (1) | Yes | 94.9 | 0.4 |
| 2 | Aluminum oxide (2) | N/A | 75.7 | 0.8 |
| | Aluminum oxide (2) | Yes | 99.6 | 0.5 |
| 3 | Quartz | N/A | 56.2 | 2.1 |
| | Quartz | Yes | 103.7 | 0.7 |
| 4 | Aluminum | N/A | 93.9 | 0.8 |
| | Aluminum | Yes | 98.6 | 0.1 |

In Sample Nos. 1 to 3 of the present disclosure, the exposed portion (without film) of the surface of the base member had hydrophilicity, and the surface of the film (with film) had water repellency even after a short time of 48 hours. From this result, Sample Nos. 1 to 3 can each be regarded as having a water-sheeting property.

### REFERENCE SIGNS

1A Film-attached member
1B Film-attached member
2A Base member made of a ceramic
2B Base member made of quartz
21 Exposed portion
3 Film
10 Plasma treatment device member

1. A film-attached member comprising:
a base member made of a ceramic, an exposed portion of a surface of the base member having hydrophilicity; and
a film of an oxide, a fluoride, an acid fluoride, or a nitride of a rare earth element on at least a portion of one surface of the base member, a surface of the film having water repellency, wherein
the film is made of yttrium oxide,
a full width at half maximum of a diffraction peak on a (222) plane of the yttrium oxide obtained by X-ray diffraction is equal to or less than 0.12°.

2. The film-attached member according to claim 1, wherein
the surface of the film has an average value of a root mean square slope (RΔq) in a roughness curve being equal to or less than 0.3.

3. The film-attached member according to claim 1, wherein
the surface of the film has an average value of a cut level difference (Rδc) representing a difference between a cut level at a load length ratio of 25% in a roughness curve and a cut level at a load length ratio of 75% in the roughness curve being equal to or less than 0.17 μm.

4. The film-attached member according to claim 1, wherein
the exposed portion of the surface of the base member has an average value of a root mean square slope (RΔq) in a roughness curve being equal to or greater than 0.001.

5. The film-attached member according to claim 1, wherein
the exposed portion of the surface of the base member has an average value of a cut level difference (Rδc) representing a difference between a cut level at a load length ratio of 25% in a roughness curve and a cut level at a load length ratio of 75% in the roughness curve being equal to or greater than 0.01 μm.

6. The film-attached member according to claim 1, wherein
the surface of the film is a polished surface.

7. The film-attached member according to claim 1, wherein
the surface of the film has an area larger than that of the exposed portion of the surface of the base member.

8. The film-attached member according to claim 1, wherein
the film has a thickness equal to or greater than 5 μm.

9. The film-attached member according to claim 1, wherein
the surface of the film has a flat shape with a flatness of the film being a convex shape equal to or greater than 3 μm.

10. The film-attached member according to claim 1, wherein
a geometric mean of a compressive stress σ11 generated in the surface of the film and a compressive stress σ2 generated in the surface of the film in a direction perpendicular to the compressive stress σ11 is equal to or greater than 120 MPa.

11. An antifouling member comprising:
the film-attached member described in claim 1.

12. The film-attached member according to claim 1, wherein
an average value of an arithmetic mean roughness (Ra) of the exposed portion of the surface of the base member is from 0.004 μm to 0.17 μm.

13. The film-attached member according to claim 1, wherein
the base member is translucent.

14. The film-attached member according to claim 1, wherein
the exposed portion of the surface of the base member has an average value of a root mean square slope (RΔq) in a roughness curve, and the surface of the film has an average value of a root mean square slope (RΔq) in a roughness curve that is larger than the average value of a root mean square slope (RΔq) in a roughness curve of the exposed portion of the surface of the base member.

15. A plasma treatment device member comprising:
the film-attached member described in claim 1.

16. A plasma treatment device comprising:
the plasma treatment device member described in claim 15.

17. A film-attached member comprising:
a base member made of quartz, an exposed portion of a surface of the base member having hydrophilicity; and
a film of an oxide, a fluoride, an acid fluoride, or a nitride of a rare earth element on at least a portion of one surface of the base member, a surface of the film having water repellency, wherein
the film is made of yttrium oxide,
a full width at half maximum of a diffraction peak on a (222) plane of the yttrium oxide obtained by X-ray diffraction is equal to or less than 0.12°.

18. The film-attached member according to claim 17, wherein the surface of the film has an average value of a root mean square slope (RΔq) in a roughness curve being equal to or less than 0.009.

19. The film-attached member according to claim 17, wherein the surface of the film has an average value of a cut level difference (Rδc) representing a difference between a cut level at a load length ratio of 25% in a roughness curve and a cut level at a load length ratio of 75% in the roughness curve being equal to or less than 0.01 μm.

20. A film-attached member comprising:
a base member made of a ceramic, an exposed portion of a surface of the base member having hydrophilicity; and
a film of an oxide, a fluoride, an acid fluoride, or a nitride of a rare earth element on at least a portion of one surface of the base member, a surface of the film having water repellency,
wherein
a geometric mean of a compressive stress σ11 generated in the surface of the film and a compressive stress σ2 generated in the surface of the film in a direction perpendicular to the compressive stress σ11 is equal to or greater than 120 MPa.
